(19) United States
(12) Patent Application Publication
(10) Pub. No.: US 2015/0362558 A1
(43) Pub. Date: Dec. 17, 2015

(54) ASSESSMENT OF THE ENERGY THAT CAN BE EXTRACTED FROM A MOTOR VEHICLE BATTERY

(71) Applicant: RENAULT S.A.S, Boulogne-Billancourt (FR)

(72) Inventors: Antoine SAINT-MARCOUX, Palaiseau (FR); Caroline MARCHAL, Montigny-Le-Bretonneux (FR)

(73) Assignee: RENAULT S.A.S., Boulogne-Billancourt (FR)

(21) Appl. No.: 14/761,443

(22) PCT Filed: Feb. 17, 2014
(86) PCT No.: PCT/FR2014/050328

§ 371 Date: Jul. 16, 2015

(30) Foreign Application Priority Data
Feb. 21, 2013 (FR) 1351488

(51) Int. Cl. G01R 31/36

(52) U.S. Cl. CPC G01R 31/3651; G01R 31/3675

(57) ABSTRACT

A method for assessing a quantity of energy that can be extracted from a motor vehicle battery including: receiving an initial temperature value and an initial battery charge status value, corresponding to an initial point in time; estimating at least one subsequent temperature value on the basis of the initial temperature value received and the initial charge status value received; determining an estimated value of the quantity of energy that can be extracted from the battery on the basis of the at least one subsequent temperature value and the initial battery charge status value.

The invention relates to the monitoring of a motor vehicle battery, in particular the assessment of the available energy in a motor vehicle battery, notably an electric or hybrid vehicle.

For a given state of charge, or SOC, the energy that can be extracted from a battery is a function of the temperature because the losses by the Joule effect associated with the displacement of the electrons depend strongly on the temperature. In effect, the lower the battery temperature, the higher the internal battery resistances. For one and the same current level, the average voltage can become lower throughout the discharge.

It is known practice to equip motor vehicles with battery management systems, BMS, that make it possible, among other things, to assess the available energy as a function notably of the outside temperature.

The document U.S. Pat. No. 6,160,380 thus describes a method for estimating the remaining capacity of a battery, in which a correction factor that is a function of the temperature is applied to take into account the influence of the outside temperature.

FIG. 1 is a graph showing the available energy as a function of the battery state-of-charge (BSOC) for different temperature values. Each curve AE_{T-T1} corresponds to a temperature Ti, between −20° C. and +20° C. It is possible, for a given state of charge and temperature, to read the available energy value, convert it into a power reserve value (distance that the client will be able to travel before running out of fuel), and display this value in order for the user to be aware of it. In other words, it is assumed that, in operation, the movement on the graph follows displacements of the type of that corresponding to the arrow F1.

Now, if the mileage value displayed is unreliable, the client risks being unsatisfied. If the available energy is underestimated, the client risks being dissuaded from taking his or her vehicle, wrongly. On the other hand, if the available energy is overestimated, the client risks running out of fuel during the journey. There is therefore a need for a method for assessing the available energy which would make it possible to improve the satisfaction of the client.

A method for assessing a quantity of energy that can be extracted from a motor vehicle battery is proposed that comprises:
receiving an initial value of a temperature parameter and an initial value of a battery state-of-charge parameter, corresponding to an initial instant,
estimating at least one subsequent value of the temperature parameter, corresponding to at least one future instant, as a function of the initial value of the temperature parameter received and of the initial value of the state-of-charge parameter received,
determining an estimated value of the quantity of energy that can be extracted from the battery as a function of that at least one subsequent value of the temperature parameter and of the initial value of the battery state-of-charge parameter.

Provision will be able to be made to transmit to a user interface a signal generated as a function of the duly determined extractable energy value.

Thus, the assessment of the available energy involves a prediction of the subsequent temperature of the battery. In other words, rather than considering that the temperature of the battery pack remains constant while the vehicle is running, the reheating associated with the use of the vehicle is taken into account. This can make it possible to better assess the available energy, and better estimate the power reserve of the motor vehicle. In effect, to return to the graph of FIG. 1, it has been observed that, when running, displacements are more of the type of that corresponding to the arrow F2 than that of the arrow F1, because of the rise in temperature of the battery while running.

The client satisfaction will therefore very likely be improved.

In particular, in the abovementioned prior art, in the case of a relatively low outside temperature, the user having left his or her vehicle parked with a battery with a fairly low charge risks seeing a very low (even zero) power reserve value displayed, whereas, in fact, the battery is not empty.

Furthermore, in the prior art, from the moment when this rise in temperature of the battery is not taken into account, the error on the estimation of the energy available in the battery can vary depending on whether the outside temperature is relatively low or relatively high.

The method described above, by thus taking into account the rise in temperature of the battery, can make it possible to limit these power reserve assessment errors.

The temperature parameter can be the temperature, a parameter proportional to the temperature, or other.

The subsequent temperature value can be a value corresponding to a certain running time, an averaged temperature value over an expected running time, or other.

The initial instant can be a start-of-journey instant, and the future instant or instants can be one or more instance during an assumed journey.

The state-of-charge parameter can be the SOC, a parameter making it possible to determine the SOC, or other.

The estimated value of the quantity of energy that can be extracted can be an extractable energy value, a value of a parameter making it possible to determine the extractable energy, or other.

The invention is in no way limited by the manner in which the subsequent temperature value or values is/are determined. For example, provision could be made to read a single temperature value from a mapping, as a function of the initial temperature value and of the state of charge.

Advantageously, and in a nonlimiting manner, provision can be made to read from a memory a value of a parameter representative of a discharge current retained in this memory, this value being generated as a function of values measured during one or more previous journey(s), for example as a function of current discharge values measured during previous journeys.

In other words, during previous discharge phases of the battery, this parameter value is learned. This may make it possible to use, for the purposes of estimating the subsequent temperature value, a parameter value representative of the discharge current corresponding more to types of driving or to expected types of journeys.

The parameter representative of a discharge current can for example be a current value, a current quadratic value, a parameter having a value proportional to the current value, or other. The invention is in no way limited to the exact nature of this parameter.

For example, in one embodiment, it will be possible to provide a mapping making it possible to associate an average temperature value with an outside temperature value, an initial state of charge and an average level of the quadratic value of the expected discharge current.

Advantageously and in a nonlimiting manner, provision can be made to model the trend of the temperature of the battery during the discharge as a function of time. This modeling can be a function notably of the value of the initial temperature of the battery received and/or of an estimated temperature value at the end of discharge.

Advantageously and in a nonlimiting manner, provision can be made to model the trend of the battery state-of-charge as a function of time.

Advantageously and in a nonlimiting manner, provision can be made to determine an end-of-discharge instant from at least the modeling of the trend of the temperature as a function of time and possibly from the modeling of the trend of the battery state-of-charge as a function of time.

Advantageously and in a nonlimiting manner, provision will be able to be made to estimate an average temperature value from a start-of-discharge instant to the duly determined end-of-discharge instant.

The invention is in no way limited to the estimation of a single subsequent temperature value. Provision could be made to determine a plurality of subsequent temperature values and compute the energy that can be extracted as a function of this plurality of values.

Nevertheless, the use of a single subsequent temperature value may make it possible to make use of a mapping to determine the extractable energy value.

This mapping may for example make it possible to associate an extractable energy value with an initial battery state-of-charge value and with the estimated average temperature value.

Advantageously and in a nonlimiting manner, provision can be made to estimate a state of health, for example a battery SOH parameter value and correct the extractable energy value obtained as a function of the estimated state-of-health value.

Advantageously and in a nonlimiting manner, the end-of-discharge instant can be determined by starting from the principle that, at the end of discharge, the state of charge of the battery is zero. The modeling of the trend of the state of charge of the battery as a function of time can then make it possible on its own to determine the end-of-discharge instant.

Advantageously and in a nonlimiting manner, it is possible to start from the assumption that the lowest state of charge which can be reached by the battery depends linearly on the temperature. The estimation of the end-of-discharge instant then involves both the modeling of the trend of the state of charge of the battery as a function of time and the modeling of the trend of the temperature as a function of time.

Advantageously and in a nonlimiting manner, a first end-of-discharge instant is computed based on a first assumption, according to which, at the end of discharge, the state of charge of the battery is zero, and a second end-of-discharge instant is computed starting from a second assumption, according to which the lowest state of charge which can be reached by the battery depends linearly on the temperature, then the lowest end-of-discharge instant out of this first and this second end-of-discharge instant is chosen.

There is also proposed a device for assessing a quantity of energy that can be extracted from a motor vehicle battery, this device comprising reception means that can receive an initial value of a temperature parameter and an initial value of a battery state-of-charge parameter, and processing means arranged to estimate at least one subsequent value of a temperature parameter, at at least one future instant, as a function of the received values of the temperature and state-of-charge parameters, and to determine an estimated value of quantity of energy that can be extracted from the battery as a function of this at least one subsequent value of the temperature parameter and of the initial value of the battery state-of-charge parameter. The device can further comprise transmission means arranged to transmit, to a user interface, a signal generated as a function of the duly determined extractable energy value.

Also proposed is a motor vehicle battery management system, for example a BMS, or other, incorporating such a device.

This system and/or this device can comprise or be incorporated in one or more processors, for example microcontrollers, microprocessors or other.

The reception means can comprise an input pin, an input port or other. The processing means can for example comprise a processor core or CPU (central processing unit). The transmission means can for example comprise an output port, an output pin or other.

Also proposed is a motor vehicle comprising a battery management system as described above, and possibly comprising a battery. This vehicle can, for example, be an electric or hybrid vehicle.

Also proposed is a computer program product comprising the instructions for performing the steps of the method described above when these instructions are executed by a processor.

The invention will be better understood with reference to the figures, which illustrate nonlimiting embodiments.

FIG. 1, already discussed, is a graph with, on the x axis, the state of charge of the battery as a %, and, on the y axis, the associated available energy, and for different temperature values.

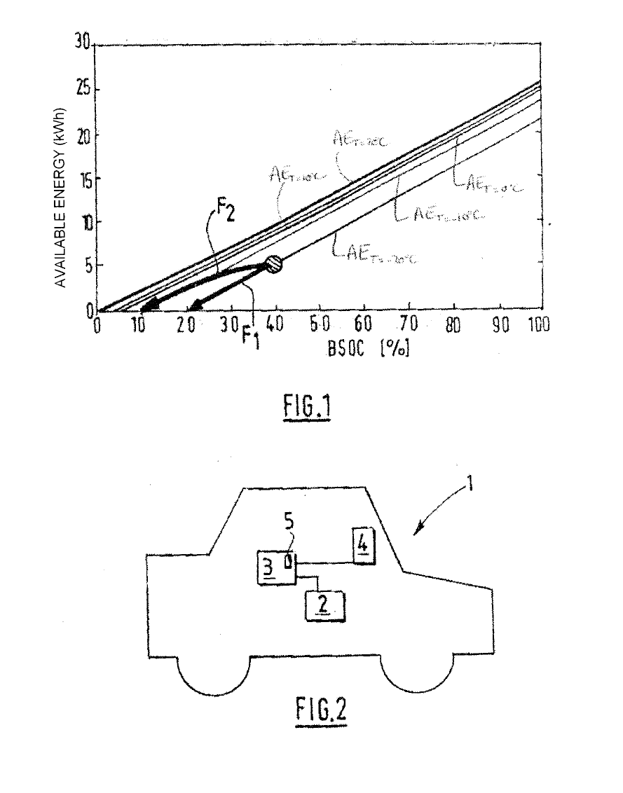

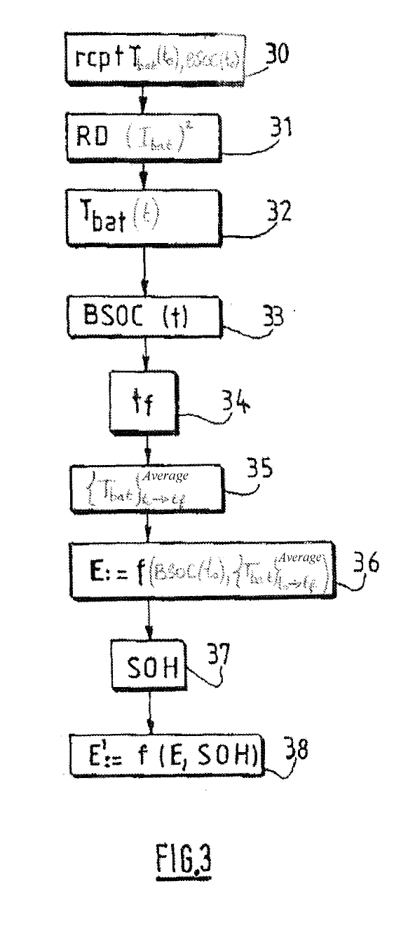

FIG. 2 shows an example of a vehicle according to an embodiment of the invention.

FIG. 3 is a flow diagram of an exemplary method according to an embodiment of the invention.

Referring to FIG. 2, a motor vehicle 1, for example an electric vehicle, can comprise a traction battery 2 capable of pulling this vehicle, a battery management system 3, called BMS, and a user interface 4, for example a dashboard.

The BMS 3 makes it possible to control the charging and the discharging of the battery 2, and makes it possible to control the display of messages on a screen (not represented) of the user interface 4.

The BMS 3 incorporates a device 5 for assessing the energy available in the battery 2, for example a part of a processor. This device 5 can notably be activated when the user activates the switch to start the vehicle, and also during a journey.

The BMS 3 is connected with temperature sensors (not represented) and voltage and current measurement devices, for example a cell voltage measurement ASIC and an ampere meter which are not represented.

Referring to FIG. 3, a method according to an embodiment of the invention can comprise a step 30 consisting in receiving an initial temperature value T_{bat}(t₀) of the battery, from a temperature sensor, and an initial state of charge of the battery value BSOC(t₀). This state-of-charge value can, for example, be from a voltage sensor at the terminals of the battery, or else from a number of sensors at the terminals of the cells of the battery.

This step 30, and more generally the method of FIG. 3, can be performed at the start of a journey, following a detection of a start-of-journey phenomenon, for example when the driver has switched on or opened the door of the vehicle.

According to a preferential embodiment, this computation can be performed at regular intervals (for example every second).

Then, an average quadratic value (I_{BAT})² of the discharge current is read in a memory during a step 31.

This value has been generated as a function of values measured during previous journeys. For example, in battery discharge phases, the BMS can compute the average level of the quadratic value of the discharge current.

According to a first embodiment, when running, the BMS can compute, at each instant, an average value (I_{BAT})² over the last kilometers traveled by the vehicle.

According to a second embodiment, the BMS can measure, over a relatively long period with a first-order low-pass filter, the term (I_{BAT})².

These values (I_{BAT})² will be able to be used to model a temperature profile as a function of time, during a step 32. During this step, the following equation is applied:

$$m \cdot {C}_{p} \cdot \frac{\partial {T}_{bat}}{\partial t} = R \cdot {( {I}_{bat} )}^{2} + ɛ - h \cdot S \cdot ( {T}_{bat} - {T}_{ext} ) \qquad ( 1 )$$

in which
m represents the weight of the battery, in kg,
Cₚ represents the heat capacity of the battery, in J/kg/K,
T_{BAT} represents the temperature of the battery, in ° C.,
R represents the internal resistance of the battery, in Ω,
I_{BAT} represents the current which passes through the battery, in A,
ε represents the heat created by a reheating system possibly present in the battery, in W,
h represents the convection coefficient between the battery and the outside, in W/m²/K,
S represents the outside exchange surface area, in m², and
Tₑₓₜ represents the outside temperature, in ° C.

In this embodiment, it is assumed that the internal resistance of the battery R varies little enough for it to be possible to retain the initial value of this resistance, or else an approximate average value, in the equation.

It is also considered that the parameters (I_{BAT})², h and ε are constant. It is then possible to characterize the rise in temperature of the battery at the instant T with the following equation:

$${T}_{bat} ( t ) = {T}_{bat} ( {t}_{0} ) + Θ \cdot ( 1 - {e}^{- \frac{( t - {t}_{0} )}{τ}} ) \qquad ( 2 )$$

with:

$$τ = \frac{m \cdot {C}_{p}}{h \cdot S}$$

and Θ being a function of the initial temperature value:

$$Θ = \frac{R \cdot {( {I}_{bat} )}^{2} + ɛ}{h \cdot S} + {T}_{ext} - {T}_{bat} ( {t}_{0} ) \qquad ( 3 )$$

Then, the trend of the state of charge of the battery over time is modeled during a step 33. More specifically, if the assumption that the discharge current is constant is maintained, it is then possible to estimate the trend of the state of charge of the battery according to the equation:

$$BSOC ( t ) = BSOC ( t ) - \frac{{I}_{BAT}}{{Q}_{ma x}} \cdot ( t - {t}_{0} ) \qquad ( 4 )$$

in which
BSOC represents the SOC of the battery, in %,
Qₘₐₓ represents the total capacity of the battery, in A.h, and
t₀ represents the state-of-discharge instant.

An end-of-discharge instant value tᵣ is then estimated during a step 34.

More specifically, a first end-of-discharge instant t_{f1} is computed starting from a first assumption according to which, at the end of the discharge, the state of charge of the battery is zero. In other words, by using the equation (4), it becomes

$${t}_{f 1} = {t}_{0} + \frac{BSOC ( {t}_{0} ) \cdot {Q}_{ma x}}{{I}_{BAT}} \qquad ( 5 )$$

A second end-of-discharge instant t_{f2} is then determined, this time by starting from the assumption that the energy available for the client is zero when the state of charge reaches a threshold which depends linearly on the temperature, that is to say that the state of charge at this end-of-discharge instant depends linearly on the temperature, according to:

BSOC(t_{f2})=A−B×T_{Bat} (6)

with A and B constant.

By coupling the equations 2, 4 and 6, the following is obtained:

$$\begin{matrix}BSOC ( {t}_{f 2} ) = BSOC ( {t}_{0} ) - \frac{{I}_{BAT}}{{Q}_{ma x}} \cdot ( {t}_{f 2} - {t}_{0} ) \\ = A - B \times \{ {T}_{bat} ( {t}_{0} ) + Θ \cdot ( 1 - {e}^{- \frac{( {t}_{f 2} - {t}_{0} )}{τ}} ) \}\end{matrix} \qquad ( 7 )$$

The second end-of-discharge instant t_{f2} is determined from this equation (7).

Then, from these two end-of-discharge instants t_{f1}, t_{f2}, the end-of-discharge instant that has the lowest value is chosen.

Now, knowing the modeling of the trend of the temperature of the battery as a function of time and the expected end-of-discharge instant, it is possible to compute an average temperature value {T_{bat}}ₜ_{₀}_{->t}_{_{f}}^{Average} between the start-of-discharge instant to and the end-of-discharge instant t_{f}, during a step 35. More specifically, it will be possible to apply an integration:

$${\{ {T}_{bat} \}}_{{t}_{0} -> {t}_{f}}^{Average} = \frac{1}{{t}_{f} - {t}_{0}} {\int }_{u = {t}_{0}}^{{t}_{f}} {T}_{bat} ( u ) \cdot d u$$

i.e., by coupling with the equation (2):

$${\{ {T}_{bat} \}}_{{t}_{0} -> {t}_{f}}^{Average} = {T}_{bat} ( {t}_{0} ) + Θ - \frac{Θ \cdot τ}{( {t}_{f} - {t}_{0} )} \cdot ( 1 - {e}^{- \frac{( {t}_{f} - {t}_{0} )}{τ}} )$$

Then, during a step 36, the extractable energy value associated with the charge value received in the step 30 and with the average temperature value {T_{bat}}ₜ_{₀}_{->t}_{_{f}}^{Average} determined in the step 35 is read from a mapping. This mapping has been generated from a new battery, for example in the workshop.

In order to take account of the effects of the aging of the battery, provision can be made to determine, during a step 37 and according to means known per se to those skilled in the art, a state of health of the battery SOH, then correct the extractable energy value as a function of the energy value determined in the step 36, and of the state of health determined in the step 37. For example, the energy value obtained in the step 36 is multiplied by the SOH coefficient of the state of degradation of the battery.

Thus, by taking into account the predictable rise in temperature for a complete discharge of the battery, it is possible to estimate the energy that can be extracted from the battery in a more reliable manner than in the prior art.

This method can thus make it possible to obtain an estimation of the power reserve of the vehicle that is less pessimistic than in the prior art, notably when the outside temperature is relatively low. This method does however imply an a priori knowledge of a model of the battery heat exchanges. It is therefore preferable to carry out tests to characterize these heat exchanges in the workshop.

The method described above can also be implemented when the vehicle is equipped with a battery heating device. The modeling of the trend of the temperature of the battery as a function of time is then adapted in order to take account of this reheating. In particular, provision will be able to be made to determine the energy cost associated with the reheating, determine the gain in terms of energy that can be extracted in the case of reheating, and to perform the reheating only if the gain is greater than the cost.

1-10. (canceled)

11. A method for assessing a quantity of energy that can be extracted from a motor vehicle battery comprising:
receiving an initial value of a temperature parameter and an initial value of a battery state-of-charge parameter, corresponding to an initial instant;
estimating at least one subsequent value of the temperature parameter, corresponding to at least one future instant, as a function of the initial value of the temperature parameter received and of the initial value of the state-of-charge parameter received;
determining an estimated value of the quantity of energy that can be extracted from the battery as a function of the at least one subsequent value of the temperature parameter and of the initial value of the battery state-of-charge parameter.

12. The method as claimed in claim 11, further comprising reading a value of a parameter representative of a battery discharge current ((I_{BAT})²) retained in memory, the value being generated as a function of current discharge values measured during at least one previous journey of the vehicle.

13. The method as claimed in claim 12, further comprising modeling a trend of the temperature parameter of the battery during the discharge as a function of time, as a function of the initial battery temperature parameter value received.

14. The method as claimed in claim 13, wherein the trend of the battery temperature parameter is modeled according to the following formula:
$${T}_{bat} ( t ) = {T}_{bat} ( {t}_{0} ) + Θ \cdot ( 1 - {e}^{- \frac{( {t}_{f} - {t}_{0} )}{τ}} ) ,$$
in which:
t represents the time,
t₀ represents the initial instant,
T_{BAT}(t) represents the modeled temperature of the battery,
T_{BAT}(t₀) represents the initial temperature value received,
Θ is a constant determined as a function of the initial temperature value received, and
τ is a constant.

15. The method as claimed in claim 11, further comprising determining an end-of-discharge instant from at least the modeling of the trend of the temperature parameter as a function of time.

16. The method as claimed in claim 15, further comprising:
computing a first end-of-discharge instant based on a first assumption, according to which, at the end of discharge, the state of charge of the battery is zero;
computing a second end-of-discharge instant starting from a second assumption, according to which the lowest state of charge which can be reached by the battery at the end of discharge depends linearly on the temperature;
choosing the lowest end-of-discharge instant from the first and the second end-of-discharge instant.

17. The method as claimed in claim 15, further comprising estimating an average temperature parameter value ({T_{bat}}ₜ_{₀}_{->t}_{_{f}}^{Average}) from the initial instant to the end-of-discharge instant.

18. The method as claimed in claim 11, further comprising modeling the trend of the battery state-of-charge parameter as a function of time.

19. A device for assessing a quantity of energy that can be extracted from a motor vehicle battery, comprising:
reception means that can receive an initial value of a temperature parameter and an initial value of a battery state-of-charge parameter, corresponding to an initial instant; and
processing means configured to estimate at least one subsequent value of the temperature parameter, corresponding to at least one future instant, as a function of the received values of the temperature and state-of-charge parameters, and configured to determine an estimated value of the quantity of energy that can be extracted from the battery as a function of the at least one subsequent value of the temperature parameter and of the initial value of the battery state-of-charge parameter.

20. A motor vehicle comprising:
a battery and a device as claimed in claim 19 for assessing a quantity of energy that can be extracted from the battery.
